(19) United States
(12) Patent Application Publication
(10) Pub. No.: US 2025/0107358 A1
(43) Pub. Date: Mar. 27, 2025

(54) DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Binyan Wang, Beijing (CN); Yonglin Guo, Beijing (CN); Dan Cao, Beijing (CN); Miao Wang, Beijing (CN); Cong Liu, Beijing (CN); Wenhui Gao, Beijing (CN); Yangpeng Wang, Beijing (CN); Gukhwan Song, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/580,905

(22) PCT Filed: Mar. 10, 2023
(86) PCT No.: PCT/CN2023/080791

§ 371 Date: Jan. 19, 2024

(51) Int. Cl. H10K 59/131

(52) U.S. Cl. CPC H10K 59/131

(57) ABSTRACT

The present disclosure provides a display substrate and a display device. The display substrate includes: a base substrate, and a compensation signal line and a plurality of sub-pixels on the base substrate. The sub-pixel includes a sub-pixel driving circuit. The sub-pixel driving circuit includes a driving transistor and a compensation structure. The compensation structure is coupled to the corresponding compensation signal line. An orthographic projection of the compensation structure onto the base substrate is located at a side of an orthographic projection of a gate electrode of the driving transistor onto the base substrate.

### TECHNICAL FIELD

The present disclosure relates to the field of display technologies, in particular to a display substrate and a display device.

### BACKGROUND

With the continuous development of display technologies, organic light-emitting diode display products have advantages of high contrast, low power consumption, light weight, good flexibility and the like, and are widely applied to various fields. The display product can also realize high-frequency display or low-frequency display according to actual display requirements.

### SUMMARY

An object of the present disclosure is to provide a display substrate and a display device.

In order to achieve the foregoing object, the present disclosure provides the following technical solutions.

A first aspect of the present disclosure provides a display substrate, including: a base substrate, and a compensation signal line and a plurality of sub-pixels on the base substrate; wherein the sub-pixel includes a sub-pixel driving circuit; the sub-pixel driving circuit includes a driving transistor and a compensation structure; the driving transistor includes a driving active pattern and a gate electrode, and an overlapping portion between an orthographic projection of the driving active pattern onto the base substrate and an orthographic projection of the gate electrode onto the base substrate, serves as a driving channel portion;

the compensation structure is coupled to the corresponding compensation signal line, and an orthographic projection of the compensation structure onto the base substrate is located on a side of an orthographic projection of the driving channel portion onto the base substrate.

Optionally, the compensation structure includes a first compensation pattern and the first compensation pattern is coupled to the corresponding compensation signal line.

Optionally, the first compensation pattern includes a first main body portion and a first extension portion coupled to each other; the first main body portion is coupled to the corresponding compensation signal line, and an orthographic projection of at least a portion of the first extension portion onto the base substrate is located between an orthographic projection of the first main body portion onto the base substrate and an orthographic projection of a gate electrode of the driving transistor onto the base substrate.

Optionally, the first extension portion includes a first portion and a second portion; the first portion and the second portion are arranged in a first direction; the first portion is respectively coupled to the first main body portion and the second portion, and in a direction perpendicular to the first direction, a width of the first portion is less than a width of the second portion.

Optionally, the first extension portion further includes a third portion; the third portion is coupled to the second portion; the third portion extends in a second direction, and the second direction intersects with the first direction.

Optionally, the first compensation pattern further includes a second extension portion coupled to the first main body portion, and an orthographic projection of the first extension portion on the base substrate is located between an orthographic projection of the second extension portion onto the base substrate and the orthographic projection of the gate electrode of the driving transistor onto the base substrate.

Optionally, the second extension portion includes a fourth portion and a fifth portion; the fourth portion and the fifth portion are arranged in a first direction; the fourth portion is respectively coupled to the first main body portion and the fifth portion, and in a direction perpendicular to the first direction, a width of the fourth portion is less than a width of the fifth portion.

Optionally, the first extension portion and the second extension portion are symmetrically arranged about a symmetry axis, and the symmetry axis is located between the first extension portion and the second extension portion and extends in a first direction.

Optionally, the first compensation pattern and the driving active pattern are arranged in a same layer of a same material.

Optionally, the compensation structure further includes a second compensation pattern; the second compensation pattern is coupled to the gate electrode of the driving transistor; an orthographic projection of the second compensation pattern onto the base substrate at least partially overlaps with the orthographic projection of the first extension portion on the base substrate; and/or, an orthographic projection of the second compensation pattern onto the base substrate at least partially overlaps with an orthographic projection of the second extension portion included in the first compensation pattern onto the base substrate.

Optionally, a portion of the first extension portion and/or the second extension portion overlapping the second compensation pattern includes a compensation channel portion.

Optionally, the orthographic projection of the second compensation pattern onto the base substrate completely covers an end of the first extension portion away from the first main body portion; and/or, the orthographic projection of the second compensation pattern onto the base substrate completely covers an end of the second extension portion away from the first main body portion.

Optionally, an orthographic projection of the second compensation pattern onto the base substrate partially overlaps an orthographic projection of the first extension portion onto the base substrate, and at least a portion of a boundary of an end of the first extension portion away from the first main body portion does not overlap an orthographic projection of the second compensation pattern onto the base substrate; and/or,

an orthographic projection of the second compensation pattern onto the base substrate partially overlaps an orthographic projection of the second extension portion onto the base substrate, and at least a portion of a boundary of an end of the second extension portion away from the first main body portion does not overlap an orthographic projection of the second compensation pattern onto the base substrate.

Optionally, the second compensation pattern and the gate electrode of the driving transistor are formed as an integrated structure.

Optionally, the first compensation pattern and the gate electrode of the driving transistor are arranged in a same layer of a same material.

Optionally, the display substrate further includes a second gate metal layer, and the first compensation pattern and the second gate metal layer are arranged in a same layer of a same material.

Optionally, the first compensation pattern includes a second main body portion and a third extension portion coupled to each other; the second main body portion is coupled to the corresponding compensation signal line, and an orthographic projection of the second main body portion onto the base substrate is located between an orthographic projection of the third extension portion onto the base substrate and an orthographic projection of the gate electrode of the driving transistor onto the base substrate.

Optionally, the display substrate further includes a first scanning line; the sub-pixel driving circuit further includes a compensation transistor; a gate electrode of the compensation transistor is coupled to the corresponding first scanning line; a first electrode of the compensation transistor is coupled to a second electrode of the driving transistor, and a second electrode of the compensation transistor is coupled to the gate electrode of the driving transistor;
the first scanning line includes at least a portion extending in a second direction, and in a layout region of the same sub-pixel, the first scanning line includes a protrusion protruding in a direction away from the first compensation pattern;
an orthographic projection of the protrusion onto the base substrate and an orthographic projection of the first compensation pattern onto the base substrate are arranged along a first direction; an orthographic projection of the first scanning line onto the base substrate does not overlap an orthographic projection of the first compensation pattern onto the base substrate, and the first direction intersects with the second direction.

Optionally, the display substrate further includes a data line; the sub-pixel driving circuit further includes a data writing transistor; a first electrode of the data writing transistor is coupled to the corresponding data line, and a second electrode of the data writing transistor is coupled to a first electrode of the driving transistor;

an orthographic projection of the first compensation pattern onto the base substrate is located between an orthographic projection of the gate electrode of the driving transistor on the base substrate and an orthographic projection of a data line coupled to a sub-pixel driving circuit to which the first compensation pattern belongs onto the base substrate.

Optionally, an orthographic projection of the first compensation pattern onto the base substrate and an orthographic projection of the gate electrode of the driving transistor onto the base substrate have a first distance, and the first distance is less than or equal to 7 μm.

Based on the technical solution of the foregoing display substrate, a second aspect of the present disclosure provides a display device, including the foregoing display substrate.

### BRIEF DESCRIPTION OF THE DRAWINGS

The drawings described herein are used to provide a further understanding of the present disclosure and constitute a part of the disclosure. The exemplary embodiments of the disclosure and the descriptions thereof are used to explain the disclosure, and do not constitute improper limitations to the disclosure. In the drawings:

FIG. 1 is a circuit structure diagram of a sub-pixel driving circuit according to an embodiment of the present disclosure;

FIG. 2 is a schematic diagram of a first layout of an active layer of a sub-pixel according to an embodiment of the present disclosure;

FIG. 3 is a schematic diagram of a first layout of an active layer and a first gate metal layer of a sub-pixel according to an embodiment of the present disclosure;

FIG. 4 is a schematic diagram of a first layout of a second gate metal layer of a sub-pixel according to an embodiment of the present disclosure;

FIG. 5 is a schematic layout diagram of a second gate metal layer illustrated in FIG. 4 on the basis of FIG. 3;

FIG. 6 is a schematic layout diagram of a light shielding layer of a sub-pixel according to an embodiment of the present disclosure;

FIG. 7 is a schematic layout diagram of the light shielding layer illustrated in FIG. 6 on the basis of FIG. 5;

FIG. 8 is a schematic layout diagram of a first source-drain metal layer of a sub-pixel according to an embodiment of the present disclosure;

FIG. 9 is a schematic layout diagram of the first source-drain metal layer illustrated in FIG. 8 on the basis of FIG. 7;

FIG. 10 is a schematic layout diagram of a second source-drain metal layer of a sub-pixel according to an embodiment of the present disclosure;

FIG. 11 is a schematic layout diagram of a second source-drain metal layer illustrated in FIG. 10 on the basis of FIG. 9;

FIG. 12 is a schematic diagram of a second layout of an active layer and a first gate metal layer of a sub-pixel according to an embodiment of the present disclosure;

FIG. 13 is a schematic layout diagram of the compensation structure in FIG. 12;

FIG. 14 is a schematic diagram of a third layout of an active layer and a first gate metal layer of a sub-pixel according to an embodiment of the present disclosure;

FIG. 15 is a schematic layout diagram of the compensation structure in FIG. 14;

FIG. 16 is a schematic diagram of a fourth layout of an active layer and a first gate metal layer of a sub-pixel according to an embodiment of the present disclosure;

FIG. 17 is a schematic layout diagram of the compensation structure in FIG. 16;

FIG. 18 is a schematic diagram of a fifth layout of an active layer and a first gate metal layer of a sub-pixel according to an embodiment of the present disclosure;

FIG. 19 is a schematic layout diagram of the compensation structure in FIG. 18;

FIG. 20 is a schematic diagram of a sixth layout of an active layer and a first gate metal layer of a sub-pixel according to an embodiment of the present disclosure;

FIG. 21 is a schematic layout diagram of the compensation structure in FIG. 20;

FIG. 22 is a schematic diagram of a seventh layout of an active layer and a first gate metal layer of a sub-pixel provided by an embodiment of the present disclosure;

FIG. 23 is a schematic layout diagram of the compensation structure in FIG. 22;

FIG. 24 is a schematic layout diagram of the active layer in FIG. 23;

FIG. 25 is a schematic diagram of an eighth layout of an active layer and a first gate metal layer of a sub-pixel according to an embodiment of the present disclosure;

FIG. 26 is a schematic layout diagram of the compensation structure in FIG. 25;

FIG. 27 is a ninth layout diagram of an active layer and a first gate metal layer of a sub-pixel provided by an embodiment of the present disclosure;

FIG. 28 is a schematic layout diagram of the compensation structure in FIG. 27;

FIG. 29 is a schematic diagram of a tenth layout of an active layer and a first gate metal layer of a sub-pixel according to an embodiment of the present disclosure.

### DETAILED DESCRIPTION

In order to further describe the display substrate and the display device provided by the embodiments of the present disclosure, a detailed description is made below combining with the accompanying drawings.

The organic light-emitting diode display product includes a plurality of sub-pixels, the sub-pixels include a sub-pixel driving circuit and a light-emitting element, and high-frequency display or low-frequency display of a display product can be realized by setting the structure of the sub-pixel driving circuit. The sub-pixel driving circuit includes a low-temperature polycrystalline silicon transistor. The transistor is coupled to a gate electrode of a driving transistor in the sub-pixel driving circuit, and is configured to perform reset or threshold voltage compensation on the gate electrode of the driving transistor.

However, due to the fact that the Ioff of the low-temperature polycrystalline silicon transistor is large, the gate electrode of the driving transistor is continuously leaked, so that the electric leakage is more serious when the low-temperature polycrystalline silicon transistor is displayed at a lower frequency, and the display effect of the display product is poor.

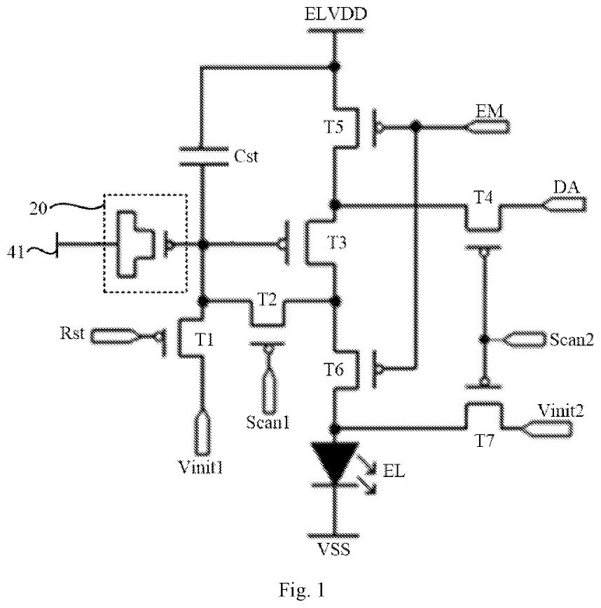

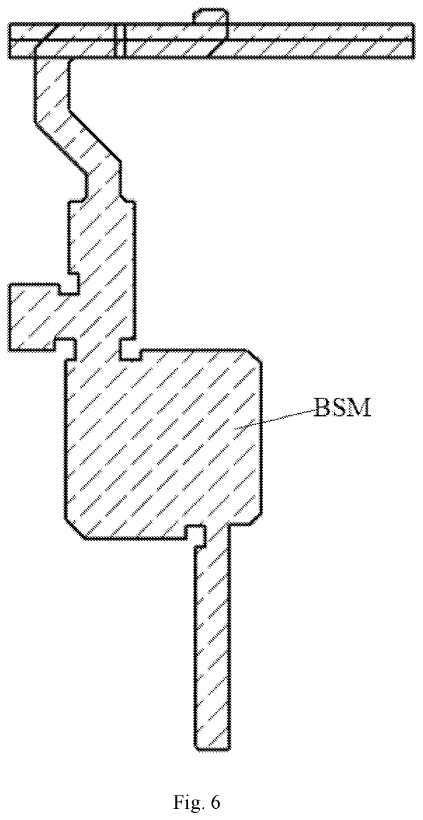

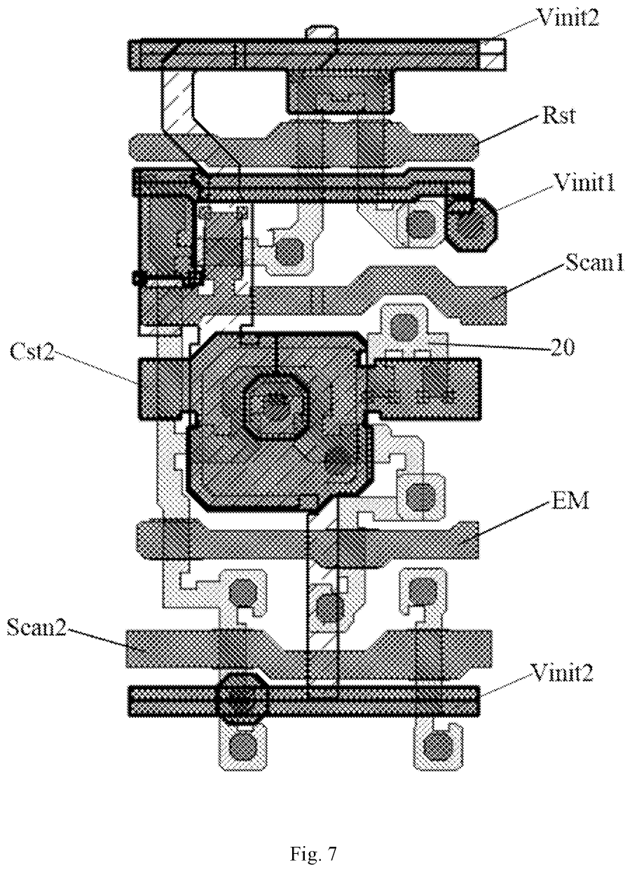

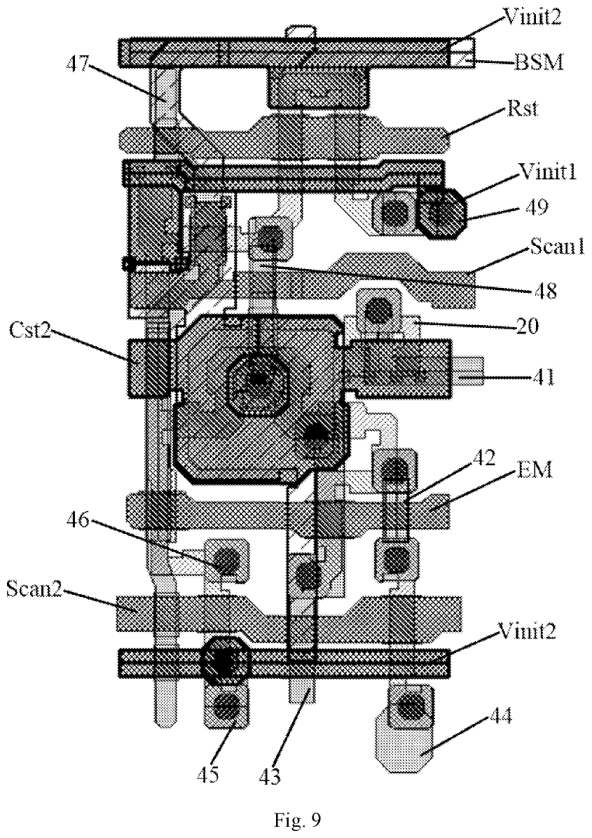

Referring to FIG. 1 to FIG. 11, an embodiment of the present disclosure provides a display substrate, including: a base substrate, and a compensation signal line 41 and a plurality of sub-pixels on the base substrate; wherein the sub-pixel includes a sub-pixel driving circuit; the sub-pixel driving circuit includes a driving transistor T3 and a compensation structure 20; the driving transistor T3 includes a driving active pattern 33 and a gate electrode, and an overlapping portion between an orthographic projection of the driving active pattern 33 onto the base substrate between an orthographic projection of the gate electrode onto the base substrate, serves as a driving channel portion 330;

the compensation structure 20 is coupled to the corresponding compensation signal line 41, and an orthographic projection of the compensation structure 20 onto the base substrate is located on a side of an orthographic projection of the driving channel portion 330 onto the base substrate.

Exemplarily, the compensation structure 20 is coupled to the corresponding compensation signal line 41. An orthographic projection of the compensation structure 20 onto the base substrate is adjacent to an orthographic projection of the driving channel portion 330 onto the base substrate.

Exemplarily, the display substrate includes a plurality of sub-pixels. A plurality of sub-pixel driving circuits included in the plurality of sub-pixels are distributed in an array. The plurality of sub-pixel driving circuits are divided into a plurality of rows of sub-pixel driving circuits and a plurality of columns of sub-pixel driving circuits. The plurality of rows of sub-pixel driving circuits are arranged in a first direction, and each row of sub-pixel driving circuits includes a plurality of sub-pixel driving circuits arranged in a second direction. The plurality of columns of sub-pixel driving circuits are arranged in a second direction, and each column of sub-pixel driving circuits includes a plurality of sub-pixel driving circuits arranged in a first direction. Exemplarily, the first direction and the second direction intersect. For example, the first direction includes a longitudinal direction, and the second direction includes a transverse direction.

Exemplarily, the sub-pixel includes a sub-pixel driving circuit and a light-emitting element. The sub-pixel driving circuit is coupled to the anode of the light-emitting element, and is configured to provide a driving signal for the light-emitting element to drive the light-emitting element to emit light.

Exemplarily, the display substrate includes a plurality of compensation signal lines 41. The compensation signals can provide a compensation signal with a fixed potential. Exemplarily, the voltage of the compensation signal is between 4V and 8V, and may include the endpoint value, but is not limited thereto. Exemplarily, the voltage value of the compensation signal includes 5V, 6V, and 7V.

Exemplarily, the compensation structure 20 is coupled to the corresponding compensation signal line 41. The compensation structure 20 has the same stable potential as the voltage of the compensation signal. It should be noted that the voltage of the compensation signal may be adjusted as required.

Exemplarily, the compensation structure 20 is coupled to the corresponding compensation signal line 41. An orthographic projection of the compensation structure 20 on the base substrate is adjacent to an orthographic projection of the driving channel portion 330 on the base substrate, that is, there are no other structures included between the orthographic projection of the compensation structure 20 on the base substrate and the orthographic projection of the driving channel portion 330 on the base substrate.

It should be noted that an orthographic projection of the driving channel portion 330 on the base substrate is completely covered by the gate electrode T3-g of the driving transistor T3, and the driving channel portion 330 includes a semiconductor portion.

Exemplarily, an orthographic projection of the compensation structure 20 on the base substrate is adjacent to an orthographic projection of the gate electrode T3-g of the driving transistor T3 on the base substrate, that is, there are no other structures included between the orthographic projection of the compensation structure 20 on the base substrate and the orthographic projection of the gate electrode T3-g of the driving transistor T3 onto the base substrate.

According to the specific structure of the display substrate, in the display substrate provided by the embodiments of the present disclosure, the compensation structure 20 is arranged near the driving channel portion 330 of the driving transistor T3, and the compensation structure 20 is coupled to the corresponding compensation signal line 41. By adjusting the compensation signal during the display process, the electric field intensity between the driving channel portion 330 and the compensation structure 20 can be changed. The electric field can affect the distribution state of the defect state particles at the interface of the driving channel portion 330, thereby achieving the effect of adjusting the hysteresis state of the driving transistor T3. At the same time, the frame is written and maintained in the low-frequency. The capacitance formed by the gate electrode T3-g of the driving transistor T3 and the voltage of the gate electrode can be adjusted and compensated by adjusting the compensation signal voltage, thereby reducing the influence of Ioff leakage on the voltage of the gate electrode under low-frequency display. Therefore, in the display substrate provided by the embodiment of the present disclosure, under the coupling action of the compensation structure 20, the leakage problem of the gate electrode T3-g of the driving transistor T3 can be compensated, and the influence of the peripheral electric field on the gate electrode T3-g of the driving transistor T3 is reduced. During low-frequency display, the leakage phenomenon is obviously improved. The brightness retention rate is effectively improved. No flicker is displayed at a low frequency, and the display effect is ensured.

The display substrate provided by the embodiments of the present disclosure can greatly improve the voltage retention rate of the voltage of the gate electrode T3-g of the driving transistor T3 in one frame in 40 Hz, 30 Hz, or even a lower frequency 24 Hz, and the Flicker effect is greatly improved.

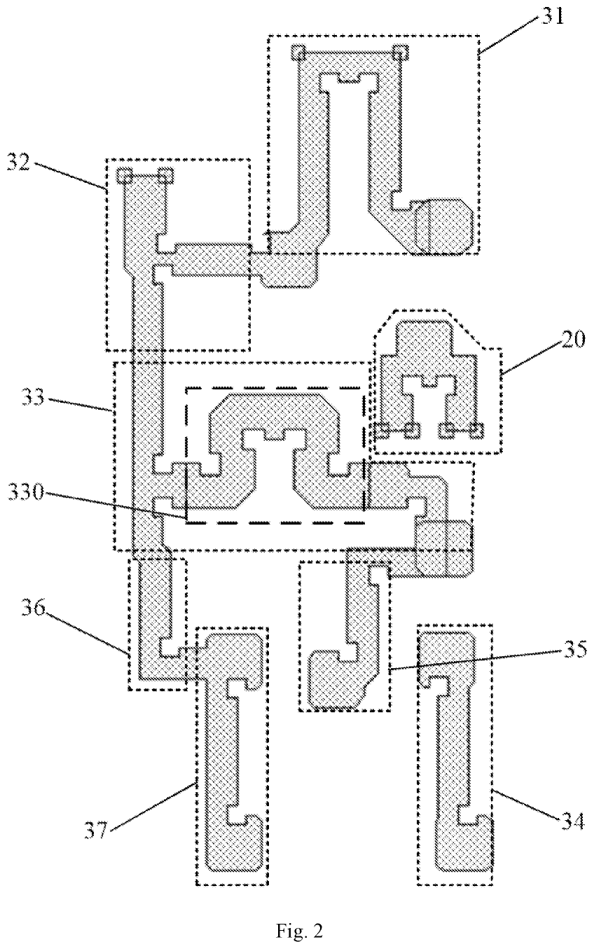

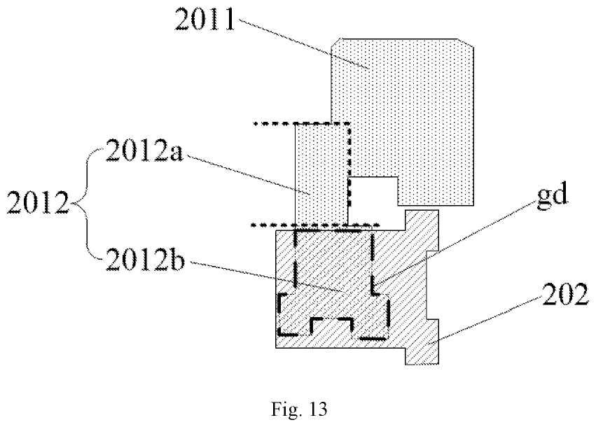

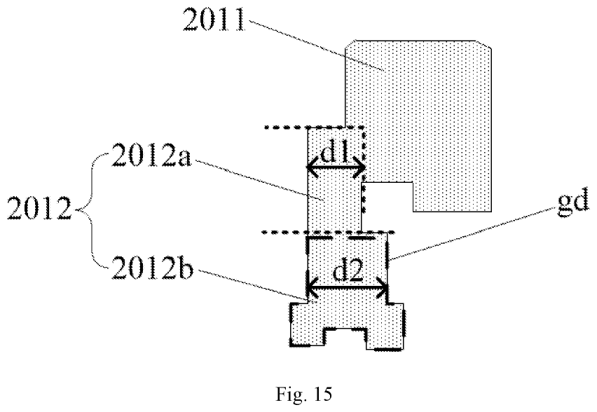

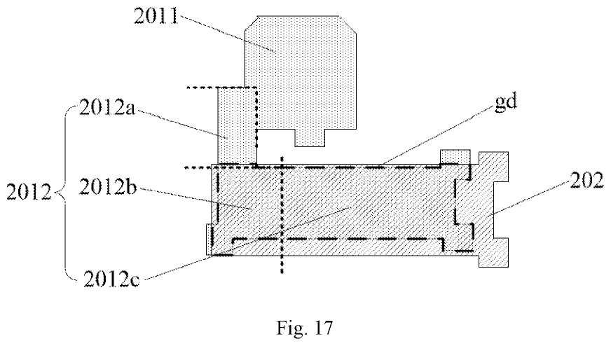

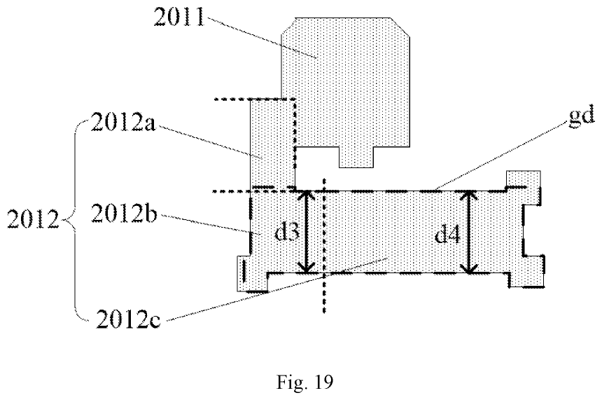

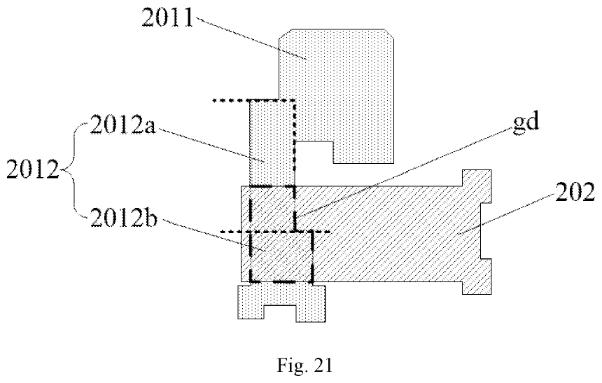

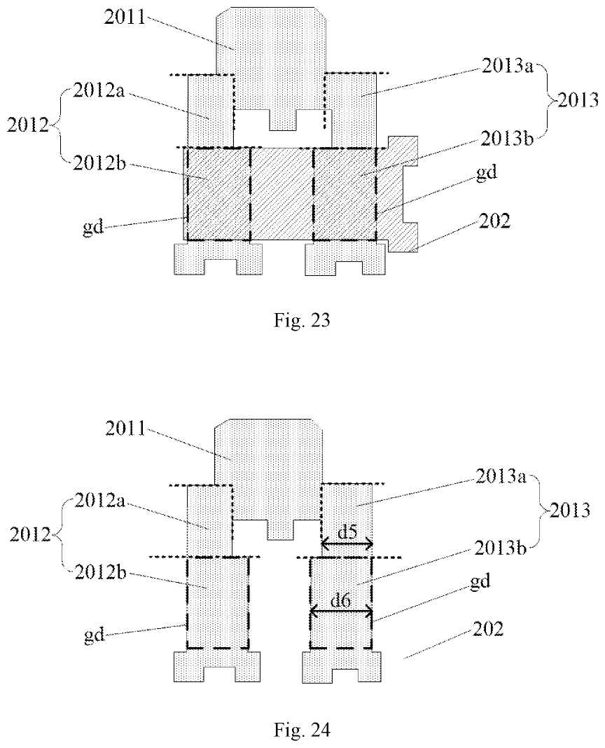

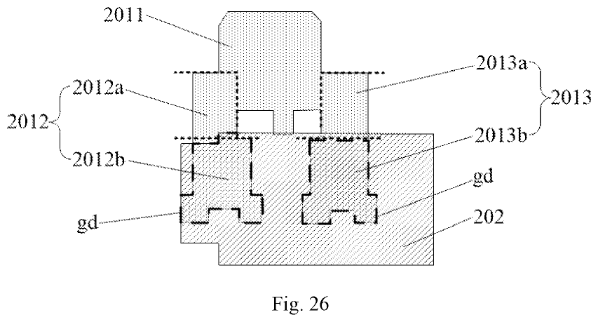

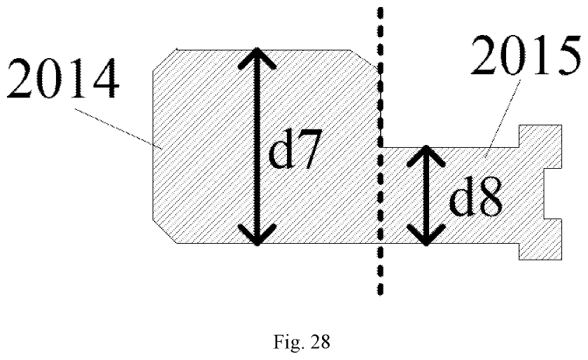

As shown in FIG. 2, FIG. 13, FIG. 15, FIG. 17, FIG. 19, FIG. 21, FIG. 23, FIG. 24, FIG. 26, and FIG. 28, in some embodiments, the compensation structure 20 includes a first compensation pattern (including a first main body portion 2011, a first extension portion 2012, a second extension portion 2013, a second main body portion 2014, and a third extension portion 2015), and the first compensation pattern is coupled to the corresponding compensation signal line 41.

Exemplarily, the first compensation pattern includes a single-layer pattern, but is not limited thereto.

Exemplarily, the first compensation pattern is made of a conductive metal material, but is not limited thereto.

Exemplarily, the display substrate includes a plurality of reset signal lines Rst, a plurality of first scan lines Scan1, a plurality of light-emitting control lines EM, and a plurality of second scan lines Scan2. In the same sub-pixel layout region, the reset signal lines Rst, the first scan lines Scan1, the light-emitting control lines EM, and the second scan lines Scan2 are sequentially arranged along the first direction. An orthographic projection of the first compensation pattern on the base substrate is located between an orthographic projection of the first scan line Scan1 on the base substrate and an orthographic projection of the light-emitting control line EM on the base substrate.

Exemplarily, the driving transistor T3 includes a driving active pattern 33. At least a portion of an orthographic projection of the first compensation pattern on the base substrate is located between an orthographic projection of the first scanning line Scan1 on the base substrate and an orthographic projection of the driving active pattern 33 on the base substrate.

Exemplarily, the sub-pixel driving circuit further includes a storage capacitor Cst. The gate electrode T3-g of the driving transistor T3 is multiplexed as a first electrode plate of the storage capacitor Cst. An orthographic projection of a second electrode plate Cst2 of the storage capacitor Cst on the base substrate at least partially overlaps with an orthographic projection of the first compensation pattern on the base substrate.

Exemplarily, the first compensation pattern and the compensation signal line 41 are arranged in different layers. An orthographic projection of the first compensation pattern on the base substrate and an orthographic projection of the compensation signal line 41 on the base substrate have an overlapping region. In the overlapping region, the first compensation pattern and the compensation signal line 41 are electrically connected through a via hole.

In the display substrate provided by the foregoing embodiments, the compensation structure 20 is set to include the first compensation pattern, so that the compensation structure 20 is simple in structure and easy to implement.

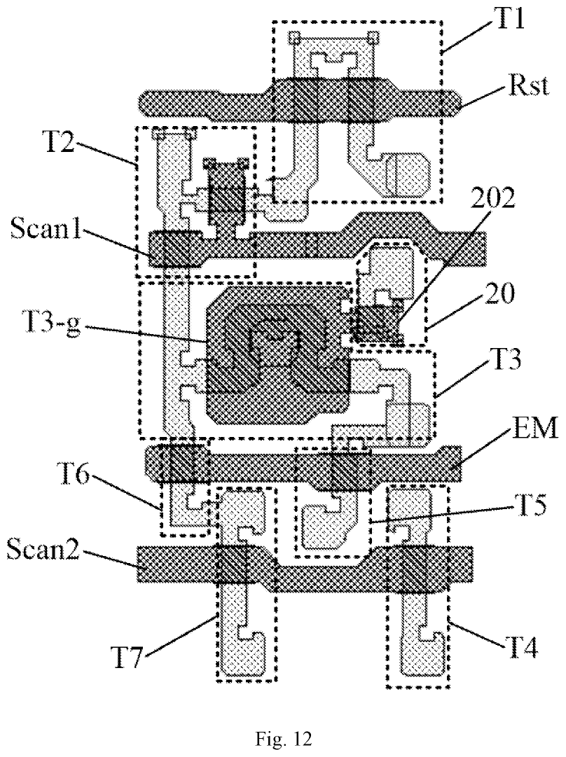

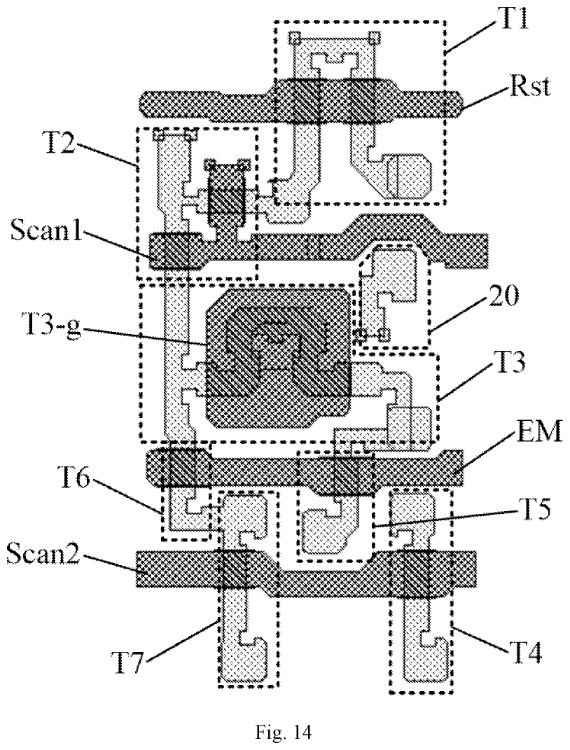

As shown in FIG. 12 to FIG. 15, in some embodiments, the first compensation pattern includes a first main body portion 2011 and a first extension portion 2012 coupled to each other; the first main body portion 2011 is coupled to the corresponding compensation signal line 41, and an orthographic projection of at least a portion of the first extension portion 2012 on the base substrate is located between an orthographic projection of the first main body portion 2011 on the base substrate and an orthographic projection of a gate electrode T3-g of the driving transistor T3 on the base substrate.

Exemplarily, the first main body portion 2011 and the first extension portion 2012 are of an integral structure, but are not limited thereto.

Exemplarily, an orthographic projection of the first main body portion 2011 on the base substrate and an orthographic projection of the compensation signal line 41 on the base substrate have an overlapping region. In the overlapping region, the first main body portion 2011 is electrically connected to the compensation signal line 41 through a via hole.

Exemplarily, an orthographic projection of the gate electrode T3-g of the driving transistor T3 on the base substrate and at least a portion of an orthographic projection of the first extension portion 2012 on the base substrate are arranged along the second direction. The orthographic projection of the gate electrode T3-g of the driving transistor T3 on the base substrate and an orthographic projection of the first main body portion 2011 on the base substrate are staggered along the second direction.

In the display substrate provided by the foregoing embodiments, by setting the first compensation pattern to include the first main body portion 2011 and the first extension portion 2012, the layout method of the first compensation pattern can be set more flexibly, and the layout difficulty of the first compensation pattern can be better reduced. Meanwhile, the reliability of connection between the first main body portion 2011 and the compensation signal line 41 is ensured, and the coupling effect can be better achieved.

In the display substrate provided by the foregoing embodiments, by setting the first compensation pattern to include the first main body portion 2011 and the first extension portion 2012, the influence of the first compensation pattern on the transmittance of the display substrate can be reduced as much as possible while ensuring the coupling effect.

As shown in FIG. 12 to FIG. 15, in some embodiments, the first extension portion 2012 includes a first portion 2012a and a second portion 2012b. The first portion 2012a and the second portion 2012b are arranged in a first direction. The first portion 2012a is coupled to the first body portion 2011 and the second portion 2012b, respectively. In a direction perpendicular to the first direction, a width d1 of the first portion 2012a is less than a width d2 of the second portion 2012b.

Exemplarily, the first portion 2012a and the second portion 2012b are of an integral structure, but are not limited thereto.

Exemplarily, an orthographic projection of the gate electrode T3-g of the driving transistor T3 on the base substrate and an orthographic projection of the second portion 2012b on the base substrate are arranged along the second direction. The orthographic projection of the gate electrode T3-g of the driving transistor T3 on the base substrate and an orthographic projection of the first portion 2012a on the base substrate are staggered along the second direction.

Exemplarily, in a direction perpendicular to the first direction, the minimum width of the first portion 2012a is less than the minimum width of the second portion 2012b.

In the display substrate provided by the foregoing embodiments, by setting the first extension portion 2012 to include the first portion 2012a and the second portion 2012b, the layout method of the first compensation pattern can be set more flexibly, and the layout difficulty of the first compensation pattern can be better reduced. Meanwhile, the reliability of connection between the first main body portion 2011 and the compensation signal line 41 is ensured, and the coupling effect can be better achieved.

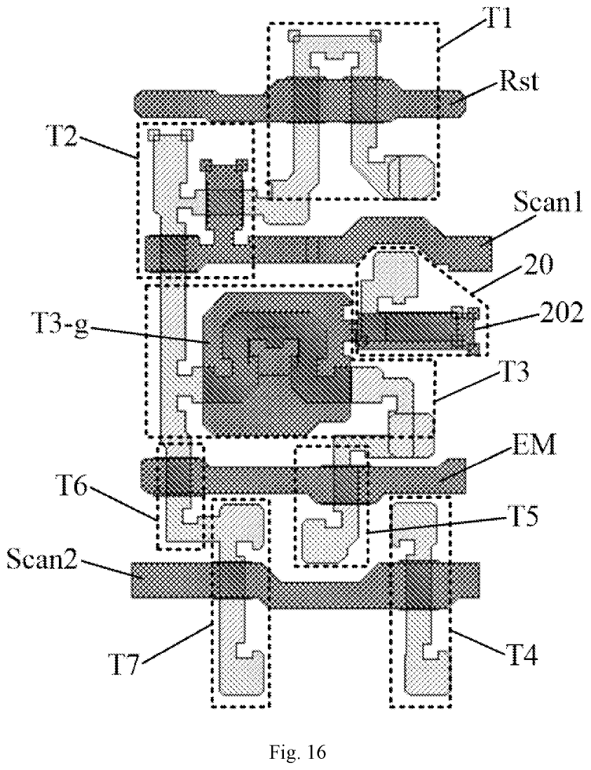

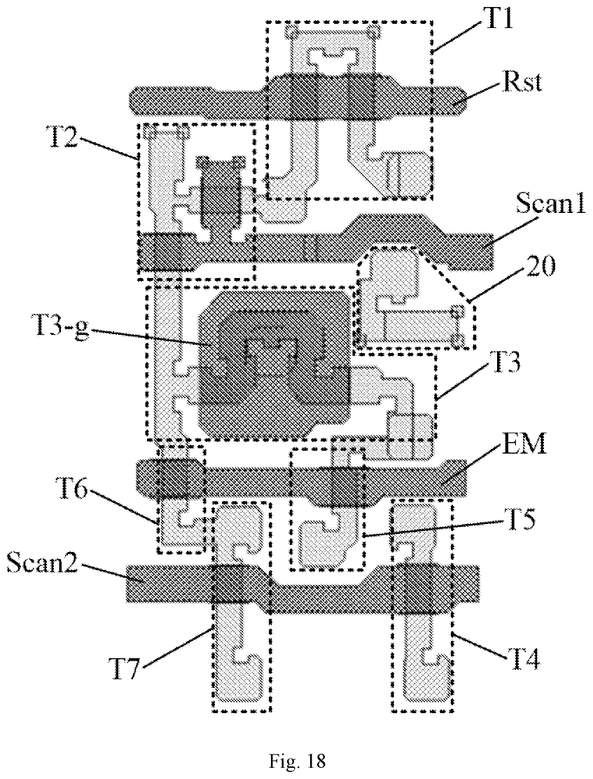

As shown in FIG. 16 to FIG. 19, in some embodiments, the first extension portion 2012 further includes a third portion 2012c. The third portion 2012c is coupled to the second portion 2012b. The third portion 2012c extends in a second direction, and the second direction intersects the first direction.

Exemplarily, the third portion 2012c and the second portion 2012b are of an integral structure, but are not limited thereto.

Exemplarily, an orthographic projection of the second portion 2012b on the base substrate is located between an orthographic projection of the third portion 2012c on the base substrate and an orthographic projection of a gate electrode T3-g of the driving transistor T3 on the base substrate.

Exemplarily, in a direction perpendicular to the second direction, the minimum width d3 of the second portion 2012b is the same as the minimum width d4 of the third portion 2012c.

In the display substrate provided by the foregoing embodiments, by setting the first extension portion 2012 to further include the third portion 2012c, the layout method of the first compensation pattern can be set more flexibly, and the layout difficulty of the first compensation pattern can be better reduced. Meanwhile, the reliability of connection between the first main body portion 2011 and the compensation signal line 41 is ensured, the area of the first extension portion 2012 is increased, and the coupling effect can be better achieved.

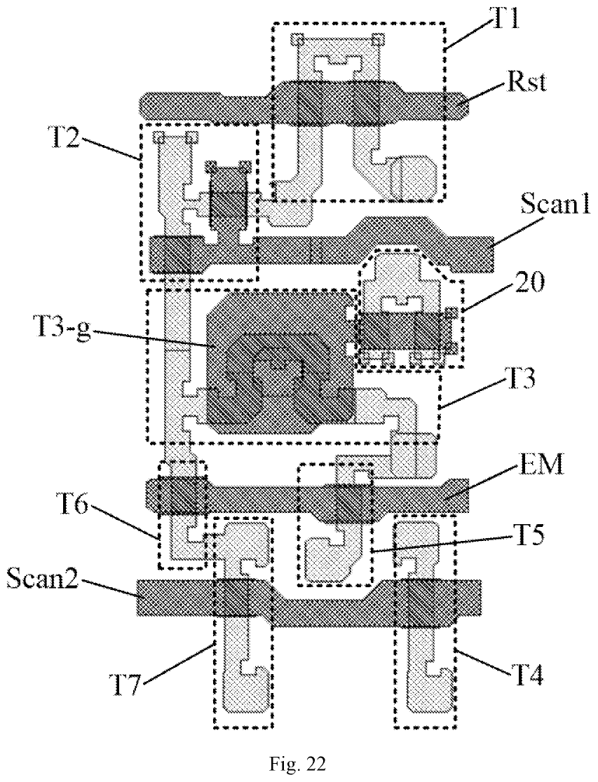

As shown in FIG. 22 to FIG. 26, in some embodiments, the first compensation pattern further includes a second extension portion 2013 coupled to the first main body portion 2011. An orthographic projection of the first extension portion 2012 on the base substrate is located between an orthographic projection of the second extension portion 2013 on the base substrate and an orthographic projection of a gate electrode T3-g of the driving transistor T3 on the base substrate.

Exemplarily, the second extension portion 2013 and the first main body portion 2011 are of an integral structure, but are not limited thereto.

Exemplarily, the second extension portion 2013 includes a fourth portion 2013a and a fifth portion 2013b. The fourth portion 2013a and the fifth portion 2013b are arranged in a first direction. The fourth portion 2013a is coupled to the first main body portion 2011 and the fifth portion 2013b, respectively. In a direction perpendicular to the first direction, a width d5 of the fourth portion 2013a is less than a width d6 of the fifth portion 2013b.

Exemplarily, the fourth portion 2013a and the fifth portion 2013b are of an integral structure.

Exemplarily, an orthographic projection of the gate electrode T3-g of the driving transistor T3 on the base substrate and an orthographic projection of the fifth portion 2013b on the base substrate are arranged along the second direction. The orthographic projection of the gate electrode T3-g of the driving transistor T3 on the base substrate and an orthographic projection of the fourth portion 2013a on the base substrate are staggered along the second direction.

Exemplarily, in a direction perpendicular to the first direction, the minimum width of the fourth portion 2013a is less than the minimum width of the fifth portion 2013b.

Exemplarily, the first extension portion 2012 and the second extension portion 2013 are symmetrically arranged about a symmetric axis, and the symmetry axis is located between the first extension portion 2012 and the second extension portion 2013 and extends in a first direction.

In the display substrate provided by the foregoing embodiments, by setting the first compensation pattern to further include a second extension portion 2013 coupled to the first main body portion 2011, not only the reliability of the connection between the first main body portion 2011 and the compensation signal line 41 is ensured, but also the area of the first compensation pattern is increased, and the coupling effect can be better achieved.

In some embodiments, the first compensation pattern and the driving active pattern are arranged in the same layer of the same material.

In the foregoing arrangement, the first compensation pattern can be simultaneously formed with the driving active pattern in the same patterning process, thereby avoiding adding an additional process specially used for manufacturing the first compensation pattern, simplifying the manufacturing process flow of the display substrate, and reducing the manufacturing cost.

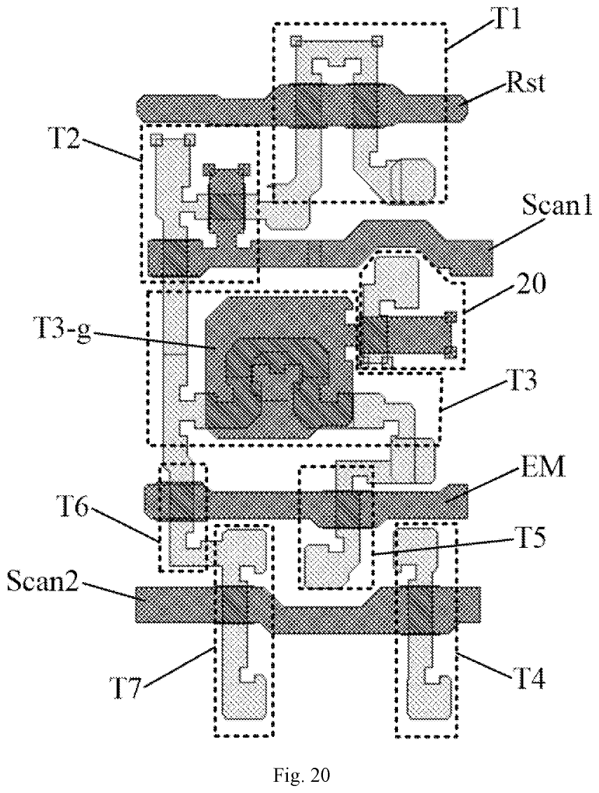

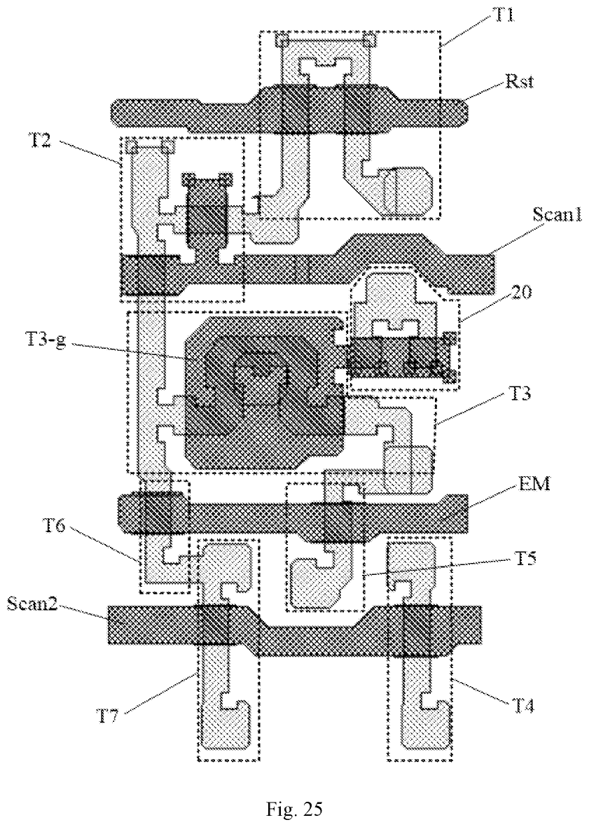

As shown in FIG. 12, FIG. 13, FIG. 16, FIG. 17, FIG. 20, FIG. 21, FIG. 22, FIG. 23, FIG. 25, and FIG. 26, in some embodiments, the compensation structure 20 further includes a second compensation pattern 202. The second compensation pattern 202 is coupled to a gate electrode T3-g of the driving transistor T3. An orthographic projection of the second compensation pattern 202 on the base substrate at least partially overlaps with an orthographic projection of the first extension portion 2012 on the base substrate; and/or, an orthographic projection of the second compensation pattern 202 on the base substrate at least partially overlaps with an orthographic projection of a second extension portion 2013 included in the first compensation pattern on the base substrate.

Exemplarily, the second compensation pattern 202 and the gate electrode T3-g of the driving transistor T3 are of an integral structure, so that the second compensation pattern 202 can be integrally formed with the gate electrode T3-g of the driving transistor T3 in the same patterning process. Not only the connection performance is ensured, but also the manufacturing process flow of the second compensation pattern 202 is simplified, and the manufacturing cost is reduced.

Exemplarily, the second compensation pattern 202 includes at least a portion extending along the second direction. The second compensation pattern 202 and the gate electrode T3-g of the driving transistor T3 are arranged in the second direction.

Exemplarily, an orthographic projection of the second compensation pattern 202 on the base substrate at least partially overlaps with an orthographic projection of a second electrode plate Cst2 of the storage capacitor Cst on the base substrate.

Exemplarily, an orthographic projection of the second compensation pattern 202 on the base substrate does not overlap an orthographic projection of a data line DA included in the display substrate on the base substrate.

Exemplarily, an orthographic projection of the second compensation pattern 202 on the base substrate at least partially overlaps with an orthographic projection of the compensation signal line 41 on the base substrate.

Exemplarily, an orthographic projection of the second compensation pattern 202 on the base substrate does not overlap an orthographic projection of the first main body portion 2011 on the base substrate.

In the display substrate provided by the foregoing embodiments, by setting the orthographic projection of the second compensation pattern 202 on the base substrate to at least partially overlap with the orthographic projection of the first extension portion 2012 on the base substrate; and/or, the orthographic projection of the second compensation pattern 202 on the base substrate to at least partially overlap with an orthographic projection of a second extension portion 2013 included in the first compensation pattern on the base substrate. The first compensation pattern and the second compensation pattern 202 are of a variable capacitor. The frame is written and maintained in the low-frequency. The voltage of the variable capacitor and the gate electrode can be adjusted and compensated by adjusting the compensation signal voltage, thereby reducing the influence of Ioff leakage on the voltage of the gate electrode under low-frequency display. Therefore, in the display substrate provided by the foregoing embodiments, the electric leakage problem of the gate electrode T3-g of the driving transistor T3 can be compensated, and the influence of the peripheral electric field on the gate electrode T3-g of the driving transistor T3 is reduced. During low-frequency display, the leakage phenomenon is obviously improved. The brightness retention rate is effectively improved. No flicker is displayed at a low frequency, and the display effect is ensured.

As shown in FIG. 20 to FIG. 26, in some embodiments, a portion of the first extension portion 2012 and/or the second extension portion 2013 overlapping the second compensation pattern 202 includes a compensation channel portion gd.

Exemplarily, the compensation channel portion gd includes a semiconductor portion. Other portions of the first extension portion 2012 and/or the second extension portion 2013 other than the compensation channel portion gd include a conductor portion, and the semiconductor portion may be formed in the same process as the channel portion of other transistors in the display substrate.

Exemplarily, the second compensation pattern 202 completely covers the compensation channel portion GD, and the second compensation pattern 202 and the first compensation pattern are formed as structures of transistors.

As shown in FIG. 22, exemplarily, the first extension portion 2012 and the second extension portion 2013 each include a compensation channel portion gd such that the second compensation pattern 202 and the first compensation pattern are formed as a double-gate transistor structure. In this structure, the first main body portion 2011, the first extension portion 2012, and the second extension portion 2013 are formed as a similar U-shaped structure.

As shown in FIG. 20, exemplarily, the first extension portion 2012 or the second extension portion 2013 includes a compensation channel portion gd, so that the second compensation pattern 202 and the first compensation pattern are formed as a single-gate transistor structure.

In the display substrate provided by the foregoing embodiments, the electric field intensity between the driving channel portion 330 and the compensation channel portion gd can be changed. The electric field can affect the distribution state of the defect state particles at the interface of the driving channel portion 330, thereby achieving the effect of adjusting the hysteresis state of the driving transistor T3.

In some embodiments, the first extension portion 2012 and/or the second extension portion 2013 include a compensation channel portion gd, and the compensation channel portion gd and the second compensation pattern do not overlap.

Exemplarily, the first extension portion 2012 and/or the second extension portion 2013 include a compensation channel portion gd, and the compensation structure 20 does not include the second compensation pattern 202.

In the display substrate provided by the foregoing embodiments, the electric field intensity between the driving channel portion 330 and the compensation channel portion gd can be changed. The electric field can affect the distribution state of the defect state particles at the interface of the driving channel portion 330, thereby achieving the effect of adjusting the hysteresis state of the driving transistor T3.

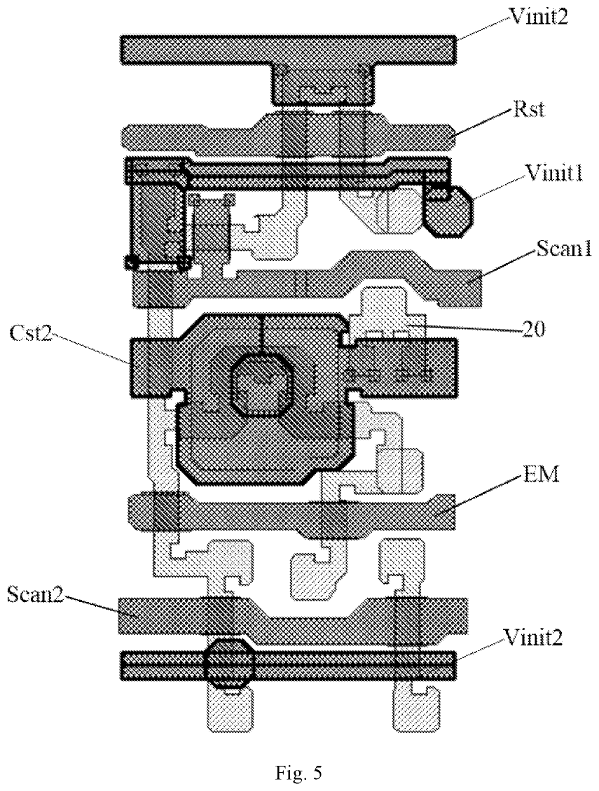

As shown in FIG. 5, FIG. 25 and FIG. 26, in some embodiments, an orthographic projection of the second compensation pattern 202 on the base substrate completely covers an end of the first extension portion 2012 away from the first main body portion 2011; and/or, an orthographic projection of the second compensation pattern 202 on the base substrate completely covers an end of the second extension portion 2013 away from the first main body portion 2011.

The foregoing arrangement can increase the overlapping area between the second compensation pattern 202 and the first compensation pattern, thereby better implementing the compensation effect on the gate electrode T3-g voltage of the driving transistor T3.

As shown in FIG. 20 to FIG. 24, in some embodiments, an orthographic projection of the second compensation pattern 202 on the base substrate partially overlaps with an orthographic projection of the first extension portion 2012 on the base substrate. An orthographic projection of the first extension portion 2012 away from one end of the first main body portion 2011 does not overlap with an orthographic projection of the second compensation pattern 202 on the base substrate.

In the foregoing arrangement, at least part of the end, away from the first main body portion 2011, of the first extension portion 2012 can extend out of the second compensation pattern 202, that is, is not covered by the second compensation pattern 202. In this way, the uniformity of the capacitance formed between the first compensation pattern and the second compensation pattern 202 in each of the sub-pixel driving circuits can be ensured, and the actual capacitance and the design difference caused by process fluctuation are better avoided, thereby better ensuring the uniformity of the plurality of sub-pixel driving circuits.

As shown in FIG. 20 to FIG. 24, in some embodiments, an orthographic projection of the second compensation pattern 202 on the base substrate partially overlaps with an orthographic projection of the second extension portion 2013 on the base substrate. An orthographic projection of the second extension portion 2013 away from one end of the first main body portion 2011 does not overlap with an orthographic projection of the second compensation pattern 202 on the base substrate.

In the foregoing arrangement, at least part of the end, away from the first main body portion 2011, of the second extension portion 2013 can extend out of the second compensation graph 202, that is, is not covered by the second compensation graph 202. In this way, the uniformity of the capacitance formed between the first compensation pattern and the second compensation pattern 202 in each of the sub-pixel driving circuits can be ensured, and the actual capacitance and the design difference caused by process fluctuation are better avoided, thereby better ensuring the uniformity of the plurality of sub-pixel driving circuits.

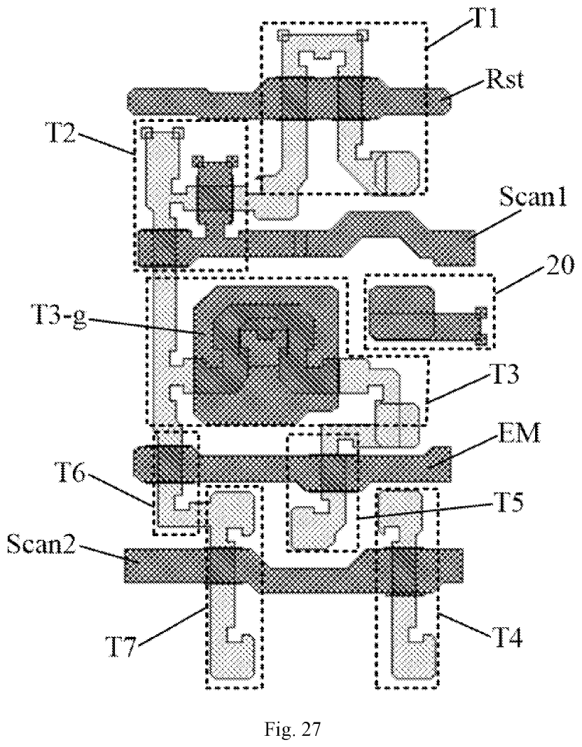

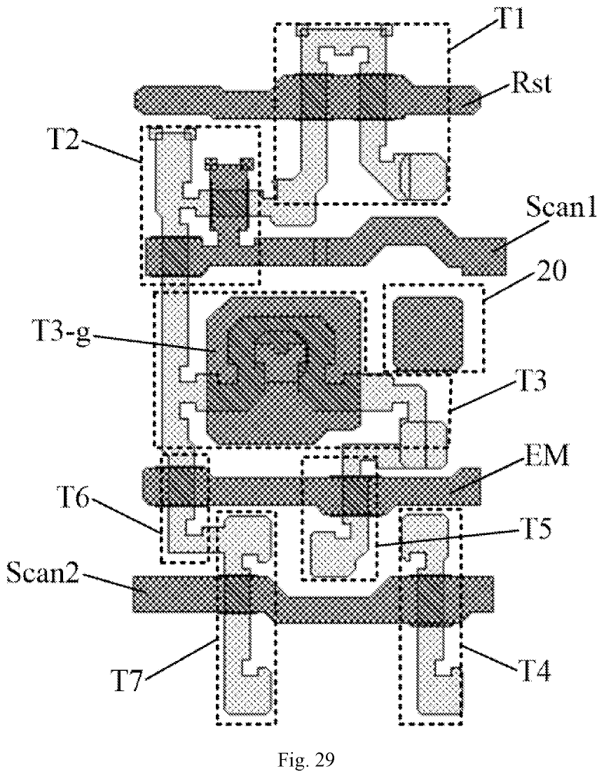

As shown in FIG. 27 to FIG. 29, in some embodiments, the first compensation pattern and the gate electrode T3-g of the driving transistor T3 are arranged in the same layer of the same material.

In the foregoing arrangement, the first compensation pattern can be formed simultaneously with the gate electrode T3-g of the driving transistor T3 in the same patterning process, so as to avoid adding an additional patterning process for manufacturing the first compensation pattern, thereby effectively simplifying the manufacturing process flow of the display substrate and reducing the manufacturing cost.

In some embodiments, the display substrate further includes a second gate metal layer, and the first compensation pattern and the second gate metal layer are arranged in the same layer of the same material.

In the foregoing arrangement, the first compensation pattern and the second gate metal layer can be simultaneously formed in the same patterning process, so as to avoid adding an additional patterning process for manufacturing the first compensation pattern, thereby effectively simplifying the manufacturing process flow of the display substrate and reducing the manufacturing cost.

In some embodiments, the display substrate further includes a first source-drain metal layer, and the first compensation pattern and the first source-drain metal layer are arranged in the same layer of the same material.

In the foregoing arrangement, the first compensation pattern can be formed simultaneously with the first source-drain metal layer in the same patterning process, so as to avoid adding an additional patterning process for manufacturing the first compensation pattern, thereby effectively simplifying the manufacturing process flow of the display substrate and reducing the manufacturing cost.

In some embodiments, the display substrate further includes a light shielding layer, and the first compensation pattern and the light shielding layer are arranged in the same layer of the same material.

In the foregoing arrangement, the first compensation pattern can be formed simultaneously with the light-shielding layer in the same patterning process, so as to avoid adding an additional patterning process in order to manufacture the first compensation pattern, thereby effectively simplifying the manufacturing process flow of the display substrate and reducing the manufacturing cost.

In some embodiments, the first compensation pattern includes a rectangular structure.

In some embodiments, the first compensation pattern includes a U-shaped structure.

As shown in FIG. 27 and FIG. 28, in some embodiments, the first compensation pattern includes a second main body portion 2014 and a third extension portion 2015 coupled to each other. The second main body portion 2014 is coupled to the corresponding compensation signal line 41. An orthographic projection of the second main body portion 2014 on the base substrate is located between an orthographic projection of the third extension portion 2015 on the base substrate and an orthographic projection of a gate electrode T3-g of the driving transistor T3 on the base substrate.

Exemplarily, the second main body portion 2014 and the third extension portion 2015 are formed as an integral structure, but are not limited thereto.

Exemplarily, the second main body portion 2014 includes a rectangle. In the first direction, the minimum width d7 of the second main body portion 2014 is greater than the minimum width d8 of the third extension portion 2015.

In the display substrate provided by the foregoing embodiments, by setting the first compensation pattern to include the second main body portion 2014 and the third extension portion 2015 coupled to each other, the layout method of the first compensation pattern can be set more flexibly, and the layout difficulty of the first compensation pattern can be better reduced. Meanwhile, the reliability of connection between the first main body portion 2011 and the compensation signal line 41 is ensured, and the coupling effect can be better achieved.

As shown in FIG. 1 to FIG. 11, in some embodiments, the display substrate further includes a first scan line Scan1. The sub-pixel driving circuit further includes a compensation transistor T2 A gate electrode of the compensation transistor T2 is coupled to the corresponding first scan line Scan1. A first electrode of the compensation transistor T 2 is coupled to a second electrode of the driving transistor T3, and a second electrode of the compensation transistor T2 is coupled to a gate electrode T3-g of the driving transistor T3;
the first scan line Scan1 includes at least a portion extending in a second direction, and in a layout region of the same sub-pixel, the first scan line Scan1 includes a protrusion Scan1-T protruding in a direction away from the first compensation pattern;
an orthographic projection of the protrusion Scan1-T on the base substrate and an orthographic projection of the first compensation pattern on the base substrate are arranged along a first direction. An orthographic projection of the first scan line Scan1 on the base substrate does not overlap an orthographic projection of the first compensation pattern on the base substrate, and the first direction intersects with the second direction.

Exemplarily, the first scan line Scan1 includes a first scan portion and a second scan portion alternately arranged along the second direction, and the second scan portion is a protrusion Scan1-T protruding in a direction away from the first compensation pattern.

In the display substrate provided by the foregoing embodiments, by setting the first scan line Scan1 to include the protrusion Scan1-T protruding in the direction away from the first compensation pattern, the protrusion Scan1-T can space out a larger layout space toward one side of the first compensation pattern. In this way, an orthographic projection of the protrusion Scan1-T on the base substrate and an orthographic projection of the first compensation pattern on the base substrate are arranged along a first direction, so that the space layout of the first compensation pattern can be better utilized, and the layout difficulty of the first compensation pattern can be reduced.

As shown in FIG. 1 to FIG. 11, in some embodiments, the display substrate further includes a data line DA. The sub-pixel driving circuit further includes a data writing transistor T4. A first electrode of the data writing transistor T4 is coupled to the corresponding data line DA, and a second electrode of the data writing transistor T4 is coupled to a first electrode of the driving transistor T3;

an orthographic projection of the first compensation pattern on the base substrate is located between an orthographic projection of a gate electrode T3-g of the driving transistor T3 on the base substrate and an orthographic projection of a data line DA coupled to a sub-pixel driving circuit to which the first compensation pattern belongs on the base substrate.

The foregoing arrangement can better shield the influence of the jump of the data signal transmitted on the data line DA on the potential of the gate electrode T3-g of the driving transistor T3.

In some embodiments, an orthographic projection of the first compensation pattern on the base substrate and an orthographic projection of the gate electrode T3-g of the driving transistor T3 on the base substrate have a first distance, and the first distance is less than or equal to 7 μm.

Exemplarily, the first distance is the minimum distance between the orthographic projection of the first compensation pattern on the base substrate and the orthographic projection of the gate electrode T3-g of the driving transistor T3 on the base substrate.

The foregoing arrangement can better compensate the leakage problem of the gate electrode T3-g of the driving transistor T3, and reduce the influence of the peripheral electric field on the gate electrode T3-g of the driving transistor T3.

As shown in FIG. 1 to FIG. 11, the display substrate further includes: a plurality of power lines ELVDD, a plurality of data lines DA, a plurality of first initialization signal lines Vinit1, a plurality of second initialization signal lines Vinit2, a plurality of first scan lines Scan1, a plurality of second scan lines Scan2, a plurality of reset signal lines Rst, and a plurality of light-emitting control lines EM.

Exemplarily, the sub-pixel driving circuit adopts a 7T1C (i.e., 7 transistors and 1 capacitor) structure, but is not limited thereto. The sub-pixel driving circuit includes a driving transistor T3, a first reset transistor T1, a compensation transistor T2, a data writing transistor T4, a power supply control transistor T5, a light-emitting control transistor T6, a second reset transistor T7, and a storage capacitor Cst.

A gate electrode of the first reset transistor T1 is coupled to the corresponding reset signal line Rst. A first electrode of the first reset transistor T1 is coupled to the corresponding first initialization signal line Vinit1, and a second electrode of the first reset transistor T1 is coupled to a second electrode of the driving transistor T3.

A gate electrode of the compensation transistor T2 is coupled to the corresponding first scan line Scan1. A first electrode of the compensation transistor T2 is coupled to a second electrode of the driving transistor T3, and a second electrode of the compensation transistor T2 is coupled to a gate electrode T3-g of the driving transistor T3.

A gate electrode of the data writing transistor T4 is coupled to a corresponding second scanning line Scan2. A first electrode of the data writing transistor T4 is coupled to a corresponding data line DA, and a second electrode of the data writing transistor T4 is coupled to a first electrode of the driving transistor T3.

A gate electrode of the power supply control transistor T5 is coupled to a corresponding light-emitting control line EM. A first electrode of the power supply control transistor T5 is coupled to a corresponding power line ELVDD, and a second electrode of the power supply control transistor T5 is coupled to a first electrode of the driving transistor T3.

A gate electrode of the light-emitting control transistor T6 is coupled to a corresponding light-emitting control line EM. A first electrode of the light-emitting control transistor T6 is coupled to a second electrode of the driving transistor T3, and a second electrode of the light-emitting control transistor T6 is coupled to an anode of a corresponding light-emitting element EL.

A gate electrode of the second reset transistor T7 is coupled to a corresponding second scan line Scan2. A first electrode of the second reset transistor T7 is coupled to a corresponding second initialization signal line Vinit2. A second electrode of the second reset transistor T7 is coupled to an anode of a corresponding light-emitting element EL, and a cathode of the light-emitting element EL receives a power supply signal VSS.

A first electrode plate of the storage capacitor Cst is coupled to a gate electrode T3-g of the driving transistor T3, and a second electrode plate Cst 2 of the storage capacitor Cst is coupled to the power line ELVDD. Exemplarily, the gate electrode T3-g of the driving transistor T3 is multiplexed as the first electrode plate of the storage capacitor Cst.

Exemplarily, the display substrate includes a light shielding layer BSM, an active layer, a first gate electrode insulating layer, a first gate metal layer, a second gate insulating layer, a second gate metal layer, an interlayer insulating layer, a first source-drain metal layer, a first planarization layer, a second source-drain metal layer, a second planarization layer, an anode layer, a light-emitting functional layer, a cathode layer, and an encapsulation layer sequentially stacked in a direction away from the base substrate. It should be noted that the display substrate may also include other film layers, such as a passivation layer.

As shown in FIG. 2, exemplarily, the first active layer includes: a first active pattern 31 in the first reset transistor T1, a second active pattern 32 in the compensation transistor T2, a driving active pattern 33 in the driving transistor T3, a fourth active pattern 34 in the data writing transistor T4, a fifth active pattern 35 in the power supply control transistor T5, a sixth active pattern 36 in the light-emitting control transistor T6, and a seventh active pattern 37 in the second reset transistor T7.

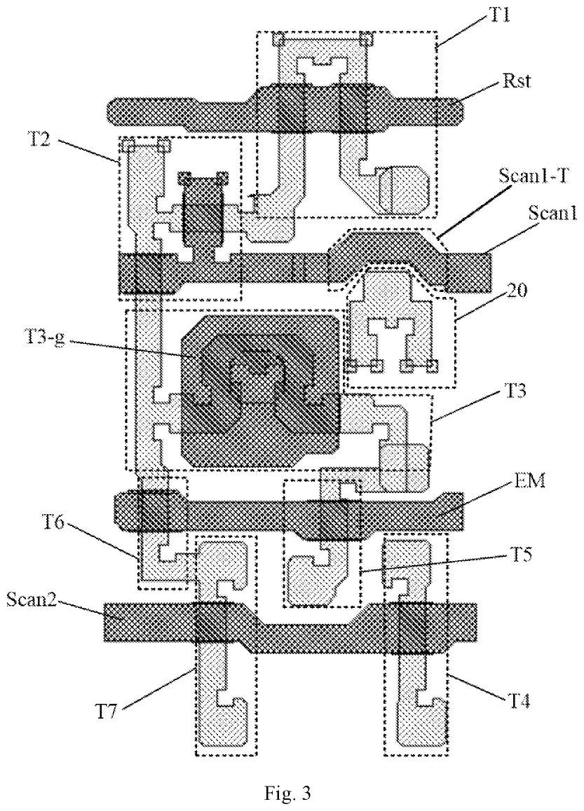

As shown in FIG. 3, exemplarily, the first gate metal layer includes a reset signal line Rst, a first scan line Scan1, a second scan line Scan2, a gate electrode T3-g of the driving transistor T3, and a light emitting control line EM.

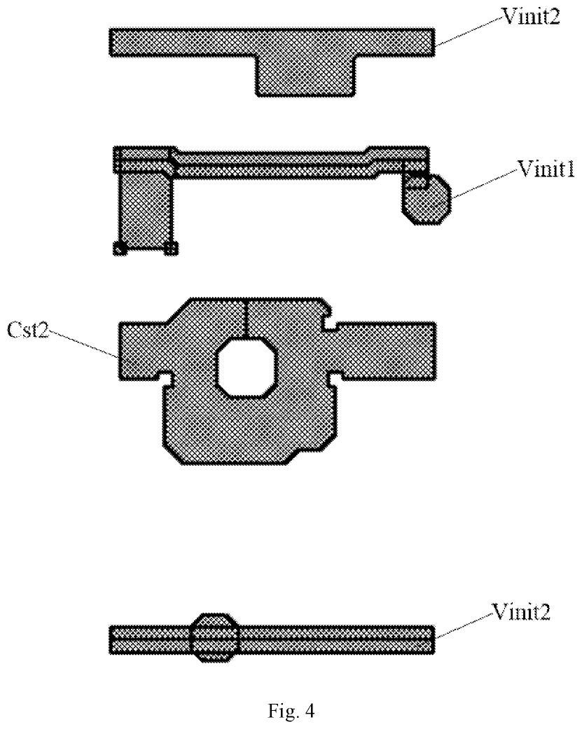

As shown in FIG. 4, exemplarily, the second gate metal layer includes a first initialization signal line Vinit1, a second initialization signal line Vinit2, and a second electrode plate Cst2 of the storage capacitor Cst.

A plurality of through holes are formed in the interlayer insulating layer. The through hole can realize the coupling between the active layer and the first source-drain metal layer.

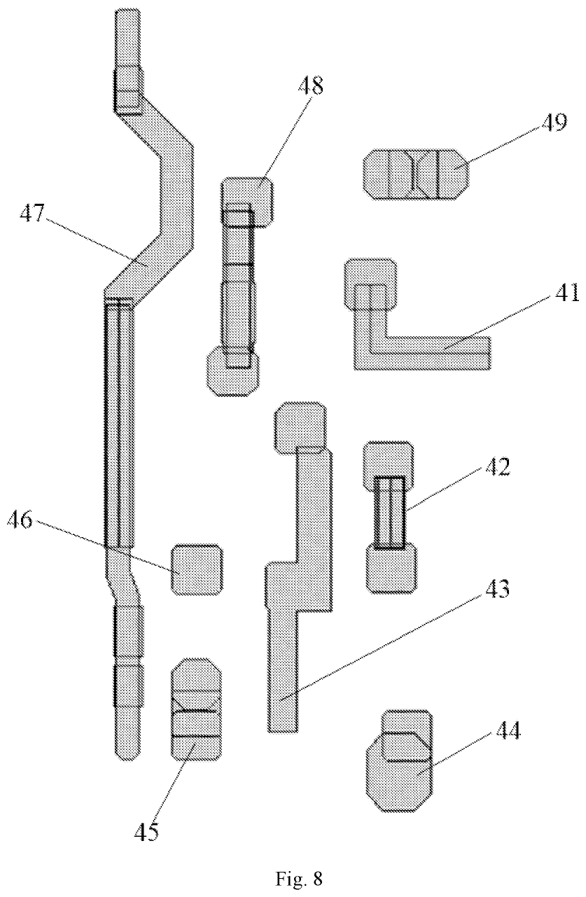

As shown in FIG. 8, exemplarily, the first source-drain metal layer includes a first conductive connection portion 41 to a ninth conductive connection portion 49. The second conductive connection portion 42 is respectively coupled to a second electrode of the data writing transistor T4 and a first electrode of the driving transistor T3. The third conductive connection portion 43 is respectively coupled to a second electrode plate Cst2 and a power line ELVDD of the storage capacitor Cst. The fourth conductive connection portion 44 is respectively coupled to a first electrode and a data line DA of the data write transistor T4. The fifth conductive connection portion 45 is respectively coupled to a first electrode and a second initialization signal line Vinit2 of the second reset transistor T7. The sixth conductive connection portion 46 is respectively coupled to a second electrode of the light-emitting control transistor T6 and a tenth conductive connection portion 50. The seventh conductive connection portion 47 is configured to connect to a second initialization signal line Vinit2 located in different rows in the display substrate. Or, the seventh conductive connection portion 47 is configured to connect compensation signal lines 41 located in different rows in the display substrate. The eighth conductive connection portion 48 is respectively coupled to a second electrode of the first reset transistor T1 and a gate electrode T3-g of the driving transistor T3. The ninth conductive connection portion 49 is respectively coupled to a first electrode of the first reset transistor T1 and a first initialization signal line Vinit1.

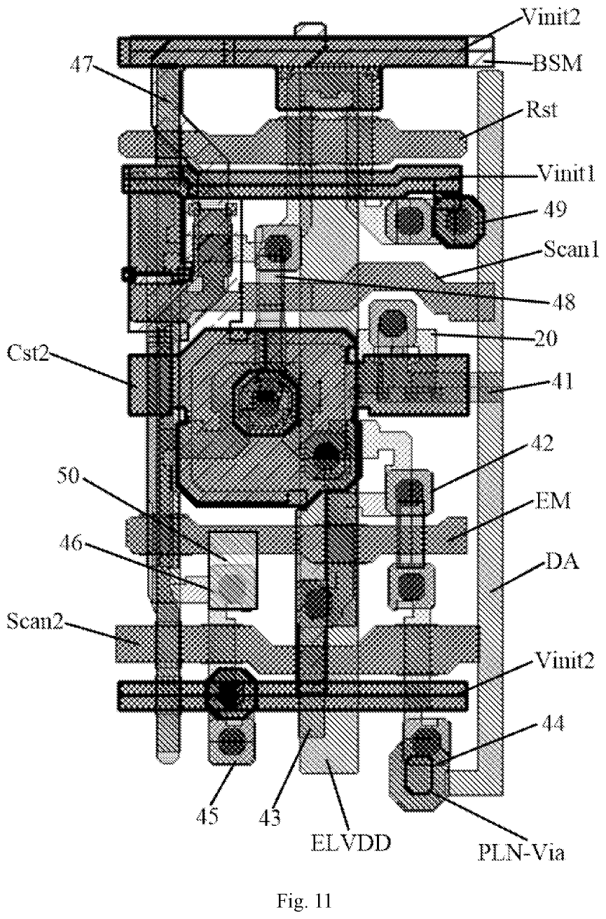

As shown in FIG. 11, exemplarily, a through hole PLN-Via is formed on the first planarization layer. The through hole PLN-Via is used for coupling between a first source-drain metal layer and a second source-drain metal layer.

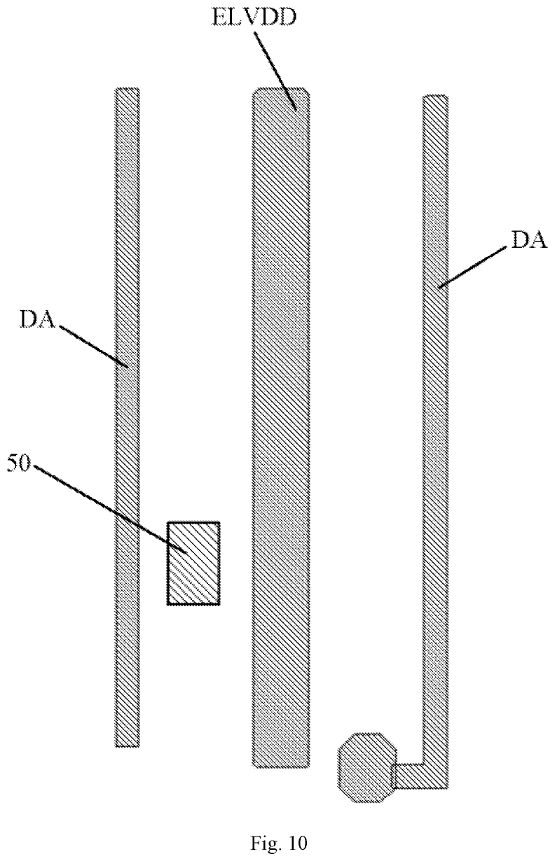

As shown in FIG. 10, exemplarily, the second source-drain metal layer includes a data line DA, a power line ELVDD, and a tenth conductive connection portion 50, and the tenth conductive connection portion 50 is respectively coupled to the sixth conductive connection portion 46 and the corresponding anode pattern.

Embodiments of the present disclosure also provide a display device, including the display substrate provided by the foregoing embodiments.

It should be noted that the display device can be: a TV, a monitor, a digital photo frame, a mobile phone, a tablet computer or any other product or component with a display function, wherein the display device also includes a flexible circuit board, a printed circuit board and a backplane, etc.

In the display substrate provided by the foregoing embodiments of the present disclosure, the compensation structure 20 is arranged near the driving channel portion 330 of the driving transistor T3, and the compensation structure 20 is coupled to the corresponding compensation signal line 41. By adjusting the compensation signal during the display process, the electric field intensity between the driving channel portion and the compensation structure 20 can be changed. The electric field can affect the distribution state of the defect state particles at the interface of the driving channel portion, thereby achieving the effect of adjusting the hysteresis state of the driving transistor. At the same time, the frame is written and maintained in the low-frequency. The capacitance formed by the gate electrode of the driving transistor and the voltage of the gate electrode can be adjusted and compensated by adjusting the compensation signal voltage, thereby reducing the influence of Ioff leakage on the voltage of the gate electrode under low-frequency display. Therefore, in the display substrate provided by the embodiment of the present disclosure, under the coupling action of the compensation structure 20, the leakage problem of the gate electrode T3-g of the driving transistor T3 can be compensated, and the influence of the peripheral electric field on the gate electrode T3-g of the driving transistor T3 is reduced. During low-frequency display, the leakage phenomenon is obviously improved. The brightness retention rate is effectively improved. No flicker is displayed at a low frequency, and the display effect is ensured.

Therefore, the display devices provided by embodiments of the present disclosure also have the foregoing beneficial effects when including the foregoing display substrate. Details are not further described herein.

It should be noted that a signal line extending along a X direction means: the signal line includes a main portion and a secondary portion connected to the main portion, the main portion is a line, a line segment or a strip-shaped body, the main portion extends along a X direction, and the length of the main portion extending along a X direction is greater than the length of the secondary portion extending along other directions.

It should be noted that “the same film layer” in an embodiment of the present disclosure may refer to a film layer located on the same structural layer. Alternatively, for example, the film layer at the same level may be a film layer formed to have a particular pattern by using the same film-forming process. The film layer may then be patterned by one patterning process using the same mask to form the desired layer structure. Depending on different particular patterns, the one patterning process may include multiple exposing, developing, or etching processes. Further, as an example, a particular pattern in the formed layer structure may be continuous or discontinuous. As other example, these particular patterns may be at different heights or have different thicknesses.

In the method embodiments of the invention, the sequential number of each step is not used to limit the order of the steps. Instead, the order of the steps may be changed by those skilled in the art without any inventive effort and is thus under the protection of the invention.

It should be noted that the various embodiments in the present description are described in a progressive manner, and the various embodiments may refer to each other for the same or similar parts, and each embodiment focuses on differences from other embodiments. Especially, for the method embodiment, since it is basically similar to the product embodiment, the description is relatively simple, and the relevant parts can be referred to the description of the product embodiment.

Unless otherwise defined, technical terms or scientific terms used in the present disclosure shall have the common meanings understood by those with ordinary skills in the field to which the present disclosure belongs. “First”, “second” and similar words used in the present disclosure do not indicate any order, quantity, or importance, but are only used to distinguish different components. “Include” or “include” and other similar words mean that the element or item before the word encompasses the element or item and their equivalents listed after the word, but does not exclude other elements or items. Similar words such as “coupled” or “connected” are not limited to physical or mechanical connections, but may include electrical connections, whether direct or indirect. “Up”, “down”, “left”, “right”, etc. are only used to indicate a relative position relationship. When an absolute position of a described object changes, the relative position relationship may also change accordingly.

It should be appreciated that, in the case that such an element as layer, film, region or substrate is arranged “on” or “under” another element, it may be directly arranged “on” or “under” the other element, or an intermediate element may be arranged therebetween.

In descriptions of the implementation modes, the specific features, structures, materials, or characteristics described may be combined in any suitable manner in any one or more embodiments or examples.

The foregoing are only specific embodiments of the present disclosure, but the protection scope of the present disclosure is not limited thereto. In the technical scope disclosed by the present disclosure, changes or substitutions easily thought by any skilled in the art are all covered in the protection scope of the present disclosure. Therefore, the protection scope of the present disclosure should be the protection scope of the claims.

1. A display substrate, comprising: a base substrate, and a compensation signal line and a plurality of sub-pixels on the base substrate; wherein the sub-pixel comprises a sub-pixel driving circuit; the sub-pixel driving circuit comprises a driving transistor and a compensation structure; the driving transistor comprises a driving active pattern and a gate electrode, and an overlapping portion between an orthographic projection of the driving active pattern onto the base substrate and an orthographic projection of the gate electrode onto the base substrate, serves as a driving channel portion;
the compensation structure is coupled to the corresponding compensation signal line, and an orthographic projection of the compensation structure onto the base substrate is located at a side of an orthographic projection of the driving channel portion onto the base substrate.

2. The display substrate according to claim 1, wherein the compensation structure comprises a first compensation pattern and the first compensation pattern is coupled to the corresponding compensation signal line.

3. The display substrate according to claim 2, wherein the first compensation pattern comprises a first main body portion and a first extension portion coupled to each other; the first main body portion is coupled to the corresponding compensation signal line, and an orthographic projection of at least a portion of the first extension portion onto the base substrate is between an orthographic projection of the first main body portion onto the base substrate and the orthographic projection of the gate electrode of the driving transistor onto the base substrate.

4. The display substrate according to claim 3, wherein the first extension portion comprises a first portion and a second portion; the first portion and the second portion are arranged in a first direction; the first portion is respectively coupled to the first main body portion and the second portion; and in a direction perpendicular to the first direction, a width of the first portion is less than a width of the second portion.

5. The display substrate according to claim 4, wherein the first extension portion further comprises a third portion; the third portion is coupled to the second portion; the third portion extends in a second direction, and the second direction intersects with the first direction.

6. The display substrate according to claim 3, wherein the first compensation pattern further comprises a second extension portion coupled to the first main body portion, and an orthographic projection of the first extension portion onto the base substrate is between an orthographic projection of the second extension portion onto the base substrate and the orthographic projection of the gate electrode of the driving transistor onto the base substrate.

7. The display substrate according to claim 6, wherein the second extension portion comprises a fourth portion and a fifth portion; the fourth portion and the fifth portion are arranged in a first direction; the fourth portion is respectively coupled to the first main body portion and the fifth portion; and in a direction perpendicular to the first direction, a width of the fourth portion is less than a width of the fifth portion.

8. The display substrate according to claim 6, wherein the first extension portion and the second extension portion are symmetrically arranged about a symmetry axis, and the symmetry axis is between the first extension portion and the second extension portion and extends in a first direction.

9. The display substrate according to claim 3, wherein the first compensation pattern and the driving active pattern are in a same layer of a same material.

10. The display substrate according to claim 9, wherein the compensation structure further comprises a second compensation pattern; the second compensation pattern is coupled to the gate electrode of the driving transistor; an orthographic projection of the second compensation pattern onto the base substrate at least partially overlaps with the orthographic projection of the first extension portion onto the base substrate; and/or, the orthographic projection of the second compensation pattern onto the base substrate at least partially overlaps with an orthographic projection of the second extension portion of the first compensation pattern onto the base substrate.

11. The display substrate according to claim 10, wherein an overlapping portion between the second compensation pattern and the first extension portion and/or the second extension portion comprises a compensation channel portion.

12. The display substrate according to claim 11, wherein the orthographic projection of the second compensation pattern onto the base substrate completely covers an end of the first extension portion away from the first main body portion; and/or, the orthographic projection of the second compensation pattern onto the base substrate completely covers an end of the second extension portion away from the first main body portion.

13. The display substrate according to claim 11, wherein the second compensation pattern and the gate electrode of the driving transistor are of an integrated structure.

14. The display substrate according to claim 2, wherein the first compensation pattern and the gate electrode of the driving transistor are in a same layer of a same material.

15. The display substrate according to claim 2, wherein the display substrate further comprises a second gate metal layer, and the first compensation pattern and the second gate metal layer are in a same layer of a same material.

16. The display substrate according to claim 14, wherein the first compensation pattern comprises a second main body portion and a third extension portion coupled to each other; the second main body portion is coupled to the corresponding compensation signal line; and an orthographic projection of the second main body portion onto the base substrate is between an orthographic projection of the third extension portion onto the base substrate and the orthographic projection of the gate electrode of the driving transistor onto the base substrate.

17. The display substrate according to claim 2, wherein the display substrate further comprises a first scanning line; the sub-pixel driving circuit further comprises a compensation transistor; a gate electrode of the compensation transistor is coupled to the corresponding first scanning line; a first electrode of the compensation transistor is coupled to a second electrode of the driving transistor, and a second electrode of the compensation transistor is coupled to the gate electrode of the driving transistor;
the first scanning line comprises at least a portion extending in a second direction; and in a layout region of the same sub-pixel, the first scanning line comprises a protrusion which protrudes in a direction away from the first compensation pattern;
an orthographic projection of the protrusion onto the base substrate and an orthographic projection of the first compensation pattern onto the base substrate are arranged along a first direction; an orthographic projection of the first scanning line onto the base substrate does not overlap the orthographic projection of the first compensation pattern onto the base substrate, and the first direction intersects with the second direction.

18. The display substrate according to claim 2, wherein the display substrate further comprises a data line; the sub-pixel driving circuit further comprises a data writing transistor; a first electrode of the data writing transistor is coupled to the corresponding data line, and a second electrode of the data writing transistor is coupled to a first electrode of the driving transistor;
an orthographic projection of the first compensation pattern onto the base substrate is between the orthographic projection of the gate electrode of the driving transistor onto the base substrate and an orthographic projection of a data line, which is coupled to a sub-pixel driving circuit to which the first compensation pattern belongs, onto the base substrate.

19. The display substrate according to claim 2, wherein there is a first distance between an orthographic projection of the first compensation pattern onto the base substrate and the orthographic projection of the gate electrode of the driving transistor onto the base substrate, and the first distance is less than or equal to 7 μm.

20. A display device, comprising a display substrate;
wherein the display substrate comprises: a base substrate, and a compensation signal line and a plurality of sub-pixels on the base substrate; wherein the sub-pixel comprises a sub-pixel driving circuit; the sub-pixel driving circuit comprises a driving transistor and a compensation structure; the driving transistor comprises a driving active pattern and a gate electrode, and an overlapping portion between an orthographic projection of the driving active pattern onto the base substrate and an orthographic projection of the gate electrode onto the base substrate, serves as a driving channel portion;
the compensation structure is coupled to the corresponding compensation signal line, and an orthographic projection of the compensation structure onto the base substrate is located at a side of an orthographic projection of the driving channel portion onto the base substrate.
